(19) United States
(12) Patent Application Publication
(10) Pub. No.: US 2025/0107401 A1
(43) Pub. Date: Mar. 27, 2025

(54) DISPLAY PANEL AND MANUFACTURING METHOD FOR THE SAME

(71) Applicant: Samsung Display Co., Ltd., Yongin-si, Gyeonggi-do (KR)

(72) Inventor: YONGHAN LEE, Yongin-si (KR)

(21) Appl. No.: 18/771,660

(22) Filed: Jul. 12, 2024

(30) Foreign Application Priority Data
Sep. 21, 2023 (KR) 10-2023-0126590

(51) Int. Cl. H10K 59/80; H10K 59/12; H10K 59/122

(52) U.S. Cl. CPC H10K 59/873; H10K 59/1201; H10K 59/122

(57) ABSTRACT

Disclosed is a display panel which comprises a base layer, a pixel-defining layer that is located on the base layer and that has a light-emitting opening defined therein, a barrier wall that has a barrier wall opening defined therein to overlap the light-emitting opening and comprises a first barrier wall layer located on the pixel-defining layer and a second barrier wall layer located on the first barrier wall layer, an inorganic pattern located in the first barrier wall layer, and a light-emitting element that is located in the barrier wall opening and that comprises an anode, an intermediate layer, and a cathode that makes contact with the barrier wall.

### CROSS-REFERENCE TO RELATED APPLICATION

The present application claims priority to, and the benefit of, Korean Patent Application No. 10-2023-0126590, filed on Sep. 21, 2023, in the Korean Intellectual Property Office, the entire disclosure of which is incorporated herein by reference.

### BACKGROUND

### 1. Field

Embodiments of the present disclosure described herein relate to a display panel with improved display quality, and a display panel manufacturing method.

### 2. Description of the Related Art

Display devices, such as a television, a monitor, a smart phone, a tablet computer, and the like, which provide an image to a user include a display panel that displays an image. Various display panels, such as a liquid crystal display panel, an organic light-emitting display panel, an electro-wetting display panel, an electrophoretic display panel, and the like, are being developed.

The organic light-emitting display panel may include anodes, cathodes, and emission patterns. The emission patterns may be divided from one another for respective emissive regions, and the cathodes may provide a common voltage for the respective emissive regions.

### SUMMARY

Embodiments of the present disclosure provide a display panel with improved display quality that includes light-emitting elements formed without the use of a metal mask, and a method for manufacturing the display panel.

According to one or more embodiments, a display panel includes a base layer, a pixel-defining layer above the base layer, and defining a light-emitting opening, a barrier wall defining a barrier wall opening overlapping the light-emitting opening, the barrier wall including a first barrier wall layer above the pixel-defining layer, and a second barrier wall layer above the first barrier wall layer, an inorganic pattern above the first barrier wall layer, and a light-emitting element in the barrier wall opening, and including an anode, an intermediate layer, and a cathode contacting the barrier wall.

The inorganic pattern may protrude further toward a center of the barrier wall opening in plan view than the first barrier wall layer.

The first barrier wall layer may include a first sub-barrier wall layer above the pixel-defining layer, and a second sub-barrier wall layer above the first sub-barrier wall layer, wherein the inorganic pattern is between the first sub-barrier wall layer and the second sub-barrier wall layer.

The cathode may contact the first sub-barrier wall layer.

The barrier wall opening may include a first region defined by a side surface of the first sub-barrier wall layer, a second region defined by a side surface of the inorganic pattern, a third region defined by a side surface of the second sub-barrier wall layer, and a fourth region defined by a side surface of the second barrier wall layer, and wherein the first to fourth regions are integrally formed in a thickness direction of the base layer.

The inorganic pattern may include a first inorganic pattern above the first sub-barrier wall layer and, a second inorganic pattern above the first inorganic pattern and covered by the second sub-barrier wall layer.

A thickness of the first inorganic pattern may be less than a thickness of the second inorganic pattern.

The first inorganic pattern may include transparent conductive oxide (TCO), wherein the second inorganic pattern includes an insulating material.

A width of the inorganic pattern may be less than a width of the barrier wall.

A region where an upper surface of the anode is exposed by the light-emitting opening and the barrier wall opening may be defined as an emissive region, wherein the inorganic pattern surrounds the emissive region in plan view.

The display panel may further include a lower inorganic encapsulation pattern above the cathode, and directly contacting the inorganic pattern.

One portion of the lower inorganic encapsulation pattern may be in the barrier wall opening, and another portion of the lower inorganic encapsulation pattern may be above the barrier wall.

The lower inorganic encapsulation pattern may be in the barrier wall opening.

According to one or more embodiments, a display panel includes a base layer, a pixel-defining layer above the base layer, and defining a light-emitting opening, a barrier wall above the pixel-defining layer, and defining a barrier wall opening overlapping the light-emitting opening, a light-emitting element in the barrier wall opening, and including an anode, an intermediate layer, and a cathode contacting the barrier wall, and an inorganic pattern surrounding, in plan view, an emissive region where an upper surface of the anode is exposed by the light-emitting opening and the barrier wall opening.

The barrier wall may include a first barrier wall layer including a first sub-barrier wall layer above the pixel-defining layer, and a second sub-barrier wall layer above the first sub-barrier wall layer, and a second barrier wall layer above the first barrier wall layer, wherein the inorganic pattern is between the first sub-barrier wall layer and the second sub-barrier wall layer.

The barrier wall opening may include a first region defined by a side surface of the first sub-barrier wall layer, a second region defined by a side surface of the inorganic pattern, a third region defined by a side surface of the second sub-barrier wall layer, and a fourth region defined by a side surface of the second barrier wall layer, and wherein the first to fourth regions are integrally formed in a thickness direction of the base layer.

The inorganic pattern may include a first inorganic pattern above the first sub-barrier wall layer, and a second inorganic pattern above the first inorganic pattern and covered by the second sub-barrier wall layer, wherein the first inorganic pattern includes transparent conductive oxide (TCO), and wherein the second inorganic pattern includes an insulating material.

The display panel may further include a lower inorganic encapsulation pattern above the cathode, and directly contacting the inorganic pattern.

One portion of the lower inorganic encapsulation pattern may be in the barrier wall opening, and another portion of the lower inorganic encapsulation pattern is above the barrier wall.

The lower inorganic encapsulation pattern may be in the barrier wall opening.

According to one or more embodiments, a method for manufacturing a display panel includes providing a preliminary display panel including a base layer, and a pixel-defining layer above the base layer, depositing a first preliminary sub-barrier wall layer above the preliminary display panel, depositing an inorganic layer above the first preliminary sub-barrier wall layer, forming an inorganic pattern by etching the inorganic layer, depositing a second preliminary sub-barrier wall layer and a preliminary metal barrier wall layer above the first preliminary sub-barrier wall layer and the inorganic pattern, and forming a barrier wall defining a barrier wall opening by etching the first preliminary sub-barrier wall layer, the second preliminary sub-barrier wall layer, and the preliminary metal barrier wall layer.

The depositing of the inorganic layer may include depositing a first inorganic layer including transparent conductive oxide (TCO) above the first preliminary sub-barrier wall layer, and depositing a second inorganic layer including an insulating material above the first inorganic layer.

The forming of the inorganic pattern may include forming a first inorganic pattern by etching the first inorganic layer, and forming a second inorganic pattern by etching the second inorganic layer.

The forming of the barrier wall may include etching the first preliminary sub-barrier wall layer, the second preliminary sub-barrier wall layer, and the preliminary metal barrier wall layer, and forming a first sub-barrier wall layer, a second sub-barrier wall layer, and a metal barrier wall layer by etching the first preliminary sub-barrier wall layer and the second preliminary sub-barrier wall layer.

The forming of the first sub-barrier wall layer, the second sub-barrier wall layer, and the metal barrier wall layer may include etching the first preliminary sub-barrier wall layer and the second preliminary sub-barrier wall layer such that the inorganic pattern protrudes further toward a center of the barrier wall opening, in plan view, than the first sub-barrier wall layer and the second sub-barrier wall layer.

The method may further include forming, in the barrier wall opening, an emission pattern and a cathode contacting the barrier wall, and forming, above the cathode, a lower inorganic encapsulation pattern configured to make direct contact with the inorganic pattern.

### BRIEF DESCRIPTION OF THE DRAWINGS

The above and other objects and features of the present disclosure will become apparent by describing in detail embodiments thereof with reference to the accompanying drawings.

FIG. 1A is a perspective view of a display device according to one or more embodiments of the present disclosure.

FIG. 1B is an exploded perspective view of the display device according to one or more embodiments of the present disclosure.

FIG. 2 is a sectional view of a display module according to one or more embodiments of the present disclosure.

FIG. 3 is a plan view of a display panel according to one or more embodiments of the present disclosure.

FIG. 4 is an enlarged plan view illustrating a portion of a display region of the display panel according to one or more embodiments of the present disclosure.

FIG. 5 is a sectional view of the display panel taken along the line I-I′ of FIG. 3 according to one or more embodiments of the present disclosure.

FIG. 6 is a sectional view of a display panel taken along the line I-I′ of FIG. 3 according to one or more embodiments of the present disclosure.

FIG. 7 is a sectional view of a display panel taken along the line I-I′ of FIG. 3 according to one or more embodiments of the present disclosure.

FIGS. 8A to 8J are sectional views illustrating some of the steps of a display panel manufacturing method according to one or more embodiments of the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object.

In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

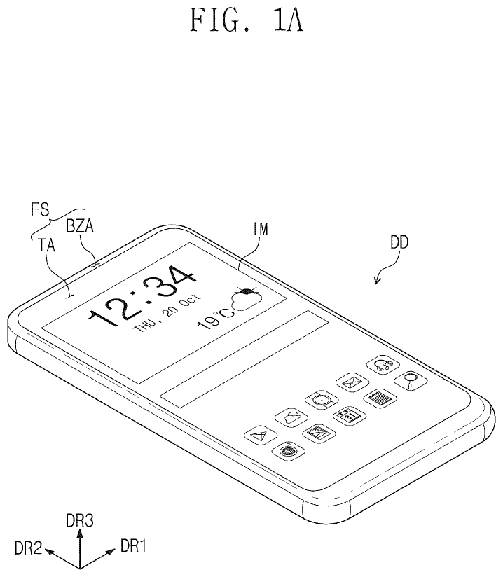

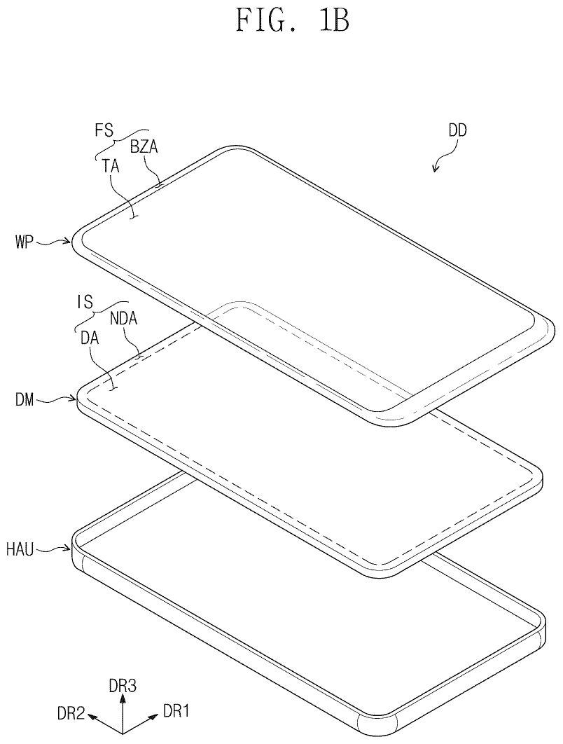

FIG. 1A is a perspective view of a display device DD according to one or more embodiments of the present disclosure. FIG. 1B is an exploded perspective view of the display device DD.

In one or more embodiments, the display device DD may be a large electronic device, such as a television, a monitor, or a billboard. Alternatively, the display device DD may be a small and medium-sized electronic device, such as a personal computer, a notebook computer, a personal digital terminal, a car navigation unit, a game machine, a smart phone, a tablet computer, or a camera. However, this is illustrative, and the display device DD may be employed as other display devices without departing from the spirit and scope of the present disclosure. In FIGS. 1A and 1B, the display device DD is illustrated as a smart phone.

Referring to FIGS. 1A and 1B, the display device DD may display an image IM in a third direction DR3 on a display surface FS parallel to a first direction DR1 and to a second direction DR2. The third direction DR3 may be a normal direction of a plane defined by the first direction DR1 and the second direction DR2. The image IM may include a still image, as well as a dynamic image. In FIG. 1A, a clock window and icons are illustrated as examples of the image IM. The display surface FS on which the image IM is displayed may correspond to the front surface of the display device DD.

Front surfaces (e.g., upper surfaces) and rear surfaces (e.g., lower surfaces) of members are defined based on the direction in which the image IM is displayed. The front surfaces and the rear surfaces may face away from each other in the third direction DR3, and the normal directions of the front surfaces and the rear surfaces may be parallel to the third direction DR3. Meanwhile, the directions indicated by the first to third directions DR1, DR2, and DR3 may be relative concepts and may be changed to other directions. As used herein, the expression “when viewed from above the plane” or “plan view” may mean that it is viewed in the third direction DR3.

The display device DD may include a window WP, a display module DM, and a housing HAU. The window WP and the housing HAU may be coupled with each other to form the exterior of the display device DD.

The window WP may include an optically clear insulating material. For example, the window WP may include glass or plastic. The front surface of the window WP may define the display surface FS of the display device DD. The display surface FS may include a transmissive region TA and a bezel region BZA. The transmissive region TA may be an optically clear region. For example, the transmissive region TA may be a region having a visible light transmittance of about 90% or more.

The bezel region BZA may be a region having a lower light transmittance than the transmissive region TA. The bezel region BZA may define the shape of the transmissive region TA. The bezel region BZA may be adjacent to the transmissive region TA, and may surround the transmissive region TA. However, this is illustrative, and the bezel region BZA of the window WP may be omitted. The window WP may include at least one of an anti-fingerprint layer, a hard coating layer, or an anti-reflection layer, and is not particularly limited.

The display module DM may be located under the window WP. The display module DM may be a component that substantially generates the image IM. The image IM generated by the display module DM is displayed on a display surface IS of the display module DM, and is visually recognized by a user from the outside through the transmissive region TA.

The display module DM may include a display region DA and a non-display region NDA. The display region DA may be a region activated depending on an electrical signal. The non-display region NDA may be adjacent to the display region DA. The non-display region NDA may surround the display region DA (e.g., in plan view). The non-display region NDA may be a region covered by the bezel region BZA, and may not be visible from the outside.

The housing HAU may be coupled with the window WP. The housing HAU may be coupled with the window WP to provide an inner space. The display module DM may be accommodated in the inner space.

The housing HAU may include a material having a relatively high rigidity. For example, the housing HAU may include glass, plastic, or metal, or may include a plurality of frames and/or plates formed of a combination of the aforementioned materials. The housing HAU may stably protect components of the display device DD accommodated in the inner space from external impact.

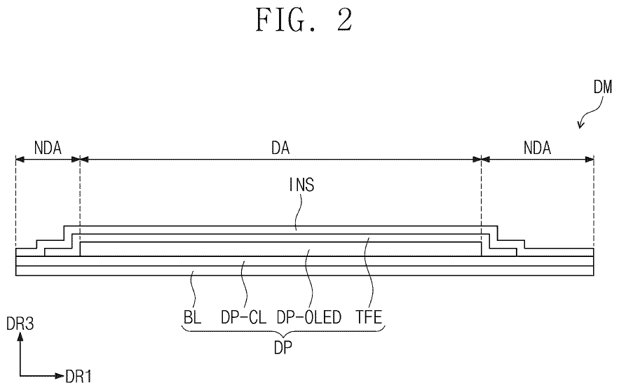

FIG. 2 is a sectional view of the display module DM according to one or more embodiments of the present disclosure.

Referring to FIG. 2, the display module DM may include a display panel DP and an input sensor INS. In one or more embodiments, the display device DD (refer to FIG. 1A) may further include a protective member located on the lower surface of the display panel DP, or an anti-reflection member and/or a window member located on the upper surface of the input sensor INS.

The display panel DP may be an emissive display panel. However, this is illustrative, and the present disclosure is not particularly limited thereto. For example, the display panel DP may be an organic light-emitting display panel or an inorganic light-emitting display panel. An emissive layer in the organic light-emitting display panel may include an organic luminescent material. An emissive layer in the inorganic light-emitting display panel may include quantum dots, quantum rods, or micro LEDs. Hereinafter, it will be exemplified that the display panel DP is an organic light-emitting display panel.

The display panel DP may include a base layer BL, and a circuit element layer DP-CL, a display element layer DP-OLED, and a thin film encapsulation layer TFE that are located on (as used herein, “located on” may mean “above”) the base layer BL. The input sensor INS may be directly located on the thin film encapsulation layer TFE. As used herein, the expression “component A is directly located on component B” means that an adhesive layer is not located between component A and component B.

The base layer BL may include at least one plastic film. The base layer BL may be a flexible substrate, and may include a plastic substrate, a glass substrate, a metal substrate, or an organic/inorganic composite substrate. The display region DA and the non-display region NDA described with reference to FIG. 1B may be identically defined in the base layer BL.

The circuit element layer DP-CL may include at least one insulating layer and a circuit element. The insulating layer may include at least one inorganic layer and at least one organic layer. The circuit element includes signal lines and a pixel drive circuit.

The display element layer DP-OLED may include a barrier wall and a light-emitting element. The light-emitting element may include an anode, an intermediate layer, and a cathode.

The thin film encapsulation layer TFE may include a plurality of thin films. Some of the thin films may improve optical efficiency, and the other thin films may protect organic light-emitting diodes.

The input sensor INS obtains coordinate information of an external input. The input sensor INS may have a multi-layer structure. The input sensor INS may include a single conductive layer or multiple conductive layers. In addition, the input sensor INS may include a single insulating layer or multiple insulating layers. The input sensor INS may sense the external input in a capacitive type. However, this is illustrative, and the present disclosure is not limited thereto. For example, in one or more embodiments, the input sensor INS may sense the external input using an electromagnetic induction method or a pressure-sensing method. Meanwhile, in one or more embodiments of the present disclosure, the input sensor INS may be omitted.

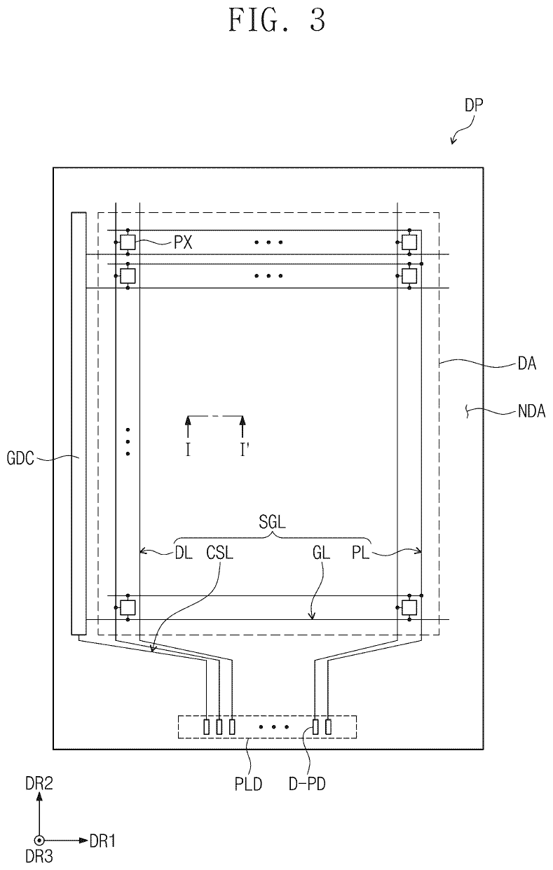

FIG. 3 is a plan view of the display panel according to one or more embodiments of the present disclosure.

Referring to FIG. 3, the display region DA, and the non-display region NDA around the display region DA, may be defined in the display panel DP. The display panel DP may include pixels PX and signal lines SGL electrically connected to the pixels PX. The display panel DP may include a drive circuit GDC and a pad part PLD. The display region DA and the non-display region NDA may be distinguished from each other depending on whether the pixels PX are located. The pixels PX may be located in the display region DA. The drive circuit GDC and the pad part PLD may be located in the non-display region NDA.

The pixels PX may be arranged in the first direction DR1 and in the second direction DR2. The pixels PX may include a plurality of pixel rows that extend in the first direction DR1, and that are arranged in the second direction DR2, and may include a plurality of pixel columns that extend in the second direction DR2, and that are arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the drive circuit GDC, and may provide control signals to the drive circuit GDC.

The drive circuit GDC may include a gate drive circuit. The gate drive circuit may generate gate signals and may sequentially output the generated gate signals to the gate lines GL. The gate drive circuit may additionally output other control signals to the pixel drive circuit.

The pad part PLD may be a part to which a flexible circuit board is connected. The pad part PLD may include pixel pads D-PD, and the pixel pads D-PD may be pads for connecting the flexible circuit board to the display panel DP. Each of the pixel pads D-PD may be connected with a corresponding signal line among the signal lines SGL. The pixel pads D-PD may be connected to the corresponding pixels PX through the signal lines SGL. Furthermore, one pixel pad among the pixel pads D-PD may be connected to the drive circuit GDC.

In addition, the pad part PLD may further include input pads. The input pads may be pads for connecting a flexible circuit board to the input sensor INS (refer to FIG. 2). However, without being limited thereto, the input pads may be located on the input sensor INS (refer to FIG. 2), and may be connected with the pixel pads D-PD and a separate circuit board. Alternatively, the input sensor INS (refer to FIG. 2) may be omitted, and the input pads may not be additionally included.

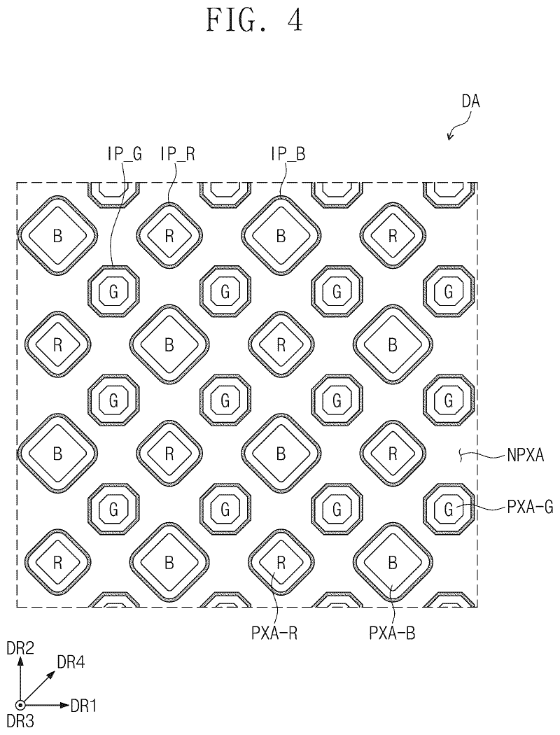

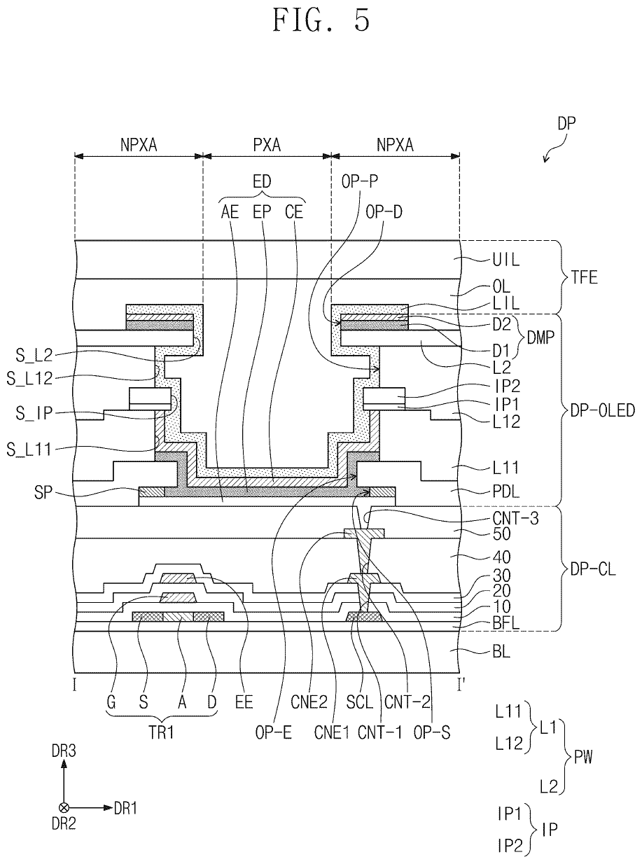

FIG. 4 is an enlarged plan view illustrating a portion of the display region DA of the display panel DP (refer to FIG. 2) according to one or more embodiments of the present disclosure. FIG. 4 is a plan view of the display module DM as viewed from above the display surface IS (refer to FIG. 1B) of the display module DM (refer to FIG. 1B) and illustrates an arrangement of emissive regions PXA-R, PXA-G, and PXA-B and an inorganic pattern IP (refer to FIG. 5).

Referring to FIG. 4, the display region DA may include the first to third emissive regions PXA-R, PXA-G, and PXA-B, and a peripheral region NPXA surrounding the first to third emissive regions PXA-R, PXA-G, and PXA-B. The first to third emissive regions PXA-R, PXA-G, and PXA-B may correspond to regions through which light provided from light-emitting elements is emitted. The first to third emissive regions PXA-R, PXA-G, and PXA-B may be distinguished from one another depending on the colors of light emitted toward the outside of the display module DM (refer to FIG. 2).

The first to third emissive regions PXA-R, PXA-G, and PXA-B may respectively provide first color light, second color light, and third color light that respectively have different colors. For example, the first color light may be red light, the second color light may be green light, and the third color light may be blue light. However, examples of the first color light, the second color light, and the third color light are not necessarily limited thereto.

Each of the first to third emissive regions PXA-R, PXA-G, and PXA-B may be defined as a region where the upper surface of an anode is exposed by a light-emitting opening and a barrier wall opening, which will be described below. The peripheral region NPXA may set the boundaries between the first to third emissive regions PXA-R, PXA-G, and PXA-B, and may reduce or prevent color mixing between the first to third emissive regions PXA-R, PXA-G, and PXA-B.

A plurality of first emissive regions PXA-R, a plurality of second emissive regions PXA-G, and a plurality of third emissive regions PXA-B may be provided. The plurality of first emissive regions PXA-R, the plurality of second emissive regions PXA-G, and the plurality of third emissive regions PXA-B may have an arrangement (e.g., a predetermined arrangement) in the display region DA, and may be repeatedly located.

For example, the first and third emissive regions PXA-R and PXA-B may be alternately arranged in the first direction DR1 to form a “first group.” The second emissive regions PXA-G may be arranged in the first direction DR1 to form a “second group.” The “first group” and the “second group” may be provided in plural numbers, and the “first groups” and the “second groups” may be alternately arranged in the second direction DR2.

One second emissive region PXA-G may be spaced apart from one first emissive region PXA-R or one third emissive region PXA-B in a fourth direction DR4. The fourth direction DR4 may be defined as a direction between the first and second directions DR1 and DR2.

Meanwhile, in FIG. 4, the arrangement of the first to third emissive regions PXA-R, PXA-G, and PXA-B is illustrated as an example, and without being limited thereto, the first to third emissive regions PXA-R, PXA-G, and PXA-B may be arranged in various forms. In one or more embodiments, the first to third emissive regions PXA-R, PXA-G, and PXA-B may have a PENTILET arrangement form as illustrated in FIG. 4 (PENTILE™ being a registered trademark of Samsung Display Co., Ltd., Republic of Korea). Alternatively, the first to third emissive regions PXA-R, PXA-G, and PXA-B may have a stripe arrangement form or a Diamond Pixel™ arrangement form (Diamond Pixel™ being a registered trademark of Samsung Display Co., Ltd., Republic of Korea).

The first to third emissive regions PXA-R, PXA-G, and PXA-B may have various shapes when viewed from above the plane. For example, the first to third emissive regions PXA-R, PXA-G, and PXA-B may have a polygonal, circular, or oval shape. FIG. 4 illustrates the first and third emissive regions PXA-R and PXA-B having a quadrangular shape (e.g., a rhombic shape) on the plane, and the second emissive regions PXA-G having an octagonal shape on the plane.

When viewed from above the plane, the first to third emissive regions PXA-R, PXA-G, and PXA-B may have the same shape, or at least some of the first to third emissive regions PXA-R, PXA-G, and PXA-B may have different shapes. FIG. 4 illustrates the first and third emissive regions PXA-R and PXA-B having the same shape on the plane, and the second emissive region PXA-G having a shape different from those of the first and third emissive regions PXA-R and PXA-B.

At least some of the first to third emissive regions PXA-R, PXA-G, and PXA-B may have different areas when viewed from above the plane. In one or more embodiments, the area of the first emissive region PXA-R emitting red light may be greater than the area of the second emissive region PXA-G emitting green light, and may be smaller than the area of the third emissive region PXA-B emitting blue light. However, the relative size relationship between the first to third emissive regions PXA-R, PXA-G, and PXA-B depending on the colors of emitted light is not limited thereto, and may vary depending on the design of the display module DM (refer to FIG. 2). Furthermore, without being limited thereto, the first to third emissive regions PXA-R, PXA-G, and PXA-B may have the same area when viewed from above the plane.

Meanwhile, the shapes, areas, and arrangement of the first to third emissive regions PXA-R, PXA-G, and PXA-B of the display module DM (refer to FIG. 2) of the present disclosure may be designed in various ways depending on the colors of emitted light, or depending on the size and configuration of the display module DM (refer to FIG. 2), and are not limited to that which is shown in FIG. 4.

Inorganic patterns IP_R, IP_G, and IP_B may be formed in the peripheral region NPXA. The inorganic patterns IP_R, IP_G, and IP_B may include the first inorganic pattern IP_R, the second inorganic pattern IP_G, and the third inorganic pattern IP_B. The inorganic patterns IP_R, IP_G, and IP_B may respectively surround the emissive regions PXA-R, PXA-G, and PXA-B when viewed from above the plane. For example, the first inorganic pattern IP_R may surround the first emissive region PXA-R when viewed from above the plane, the second inorganic pattern IP_G may surround the second emissive region PXA-G when viewed from above the plane, and the third inorganic pattern IP_B may surround the third emissive region PXA-B when viewed from above the plane. The inorganic patterns IP_R, IP_G, and IP_B may be located in a first barrier wall layer L1 (refer to FIG. 5) of a barrier wall PW (refer to FIG. 5) that will be described below.

FIG. 5 is a sectional view of the display panel taken along the line I-I′ of FIG. 3 according to one or more embodiments of the present disclosure. In describing FIG. 5, the description will be made with reference to FIG. 2, and descriptions of the same reference numerals will be omitted.

FIG. 5 is a blowup of one emissive region PXA in the display region DA (refer to FIG. 4), and the emissive region PXA of FIG. 5 may correspond to one of the first to third emissive regions PXA-R, PXA-G, and PXA-B of FIG. 4. Furthermore, in FIG. 5, one inorganic pattern IP corresponding to the emissive region PXA among the first to third inorganic patterns IP_R, IP_G, and IP_B is illustrated.

Referring to FIG. 5, the display panel DP may include the base layer BL, the circuit element layer DP-CL, the display element layer DP-OLED, and the thin film encapsulation layer TFE.

The display panel DP may include a plurality of insulating layers, a semiconductor pattern, a conductive pattern, and a signal line. An insulating layer, a semiconductor layer, and a conductive layer are formed by coating, deposition, or the like. Thereafter, the insulating layer, the semiconductor layer, and the conductive layer may be selectively subjected to patterning by photolithography and etching. The semiconductor pattern, the conductive pattern, and the signal line included in the circuit element layer DP-CL and the display element layer DP-OLED may be formed by the above-described method.

The circuit element layer DP-CL may be located on the base layer BL. The circuit element layer DP-CL may include a buffer layer BFL, a transistor TR1, a signal transmission region SCL, first to fifth insulating layers 10, 20, 30, 40, and 50, an electrode EE, and a plurality of connecting electrodes CNE1 and CNE2.

The buffer layer BFL may be located on the base layer BL. The buffer layer BFL may improve the coupling force between the base layer BL and a semiconductor pattern. The buffer layer BFL may include silicon oxide layers and silicon nitride layers. The silicon oxide layers and the silicon nitride layers may be alternately stacked one above another.

The semiconductor pattern may be located on the buffer layer BFL. The semiconductor pattern may include poly-silicon. However, without being limited thereto, the semiconductor pattern may include amorphous silicon or metal oxide. In FIG. 5, a portion of the semiconductor pattern is illustrated as an example, and the semiconductor pattern may be additionally located in the plurality of emissive regions PXA-R, PXA-G, and PXA-B (refer to FIG. 4). The semiconductor pattern may be arranged across the plurality of emissive regions PXA-R, PXA-G, and PXA-B according to a specific rule. The semiconductor pattern may have different electrical properties depending on whether the semiconductor pattern is doped or not. The semiconductor pattern may include a first region having a high doping concentration and a second region having a low doping concentration. The first region may be doped with an N-type dopant or a P-type dopant. A P-type transistor may include a first region doped with a P-type dopant.

The first region has a higher conductivity than the second region, and substantially serves as an electrode or a signal line. The second region may substantially correspond to an active region (e.g., a channel region) of the transistor. In other words, one portion of the semiconductor pattern may be the active region of the transistor, another portion may be a source or drain of the transistor, and another portion may be a conductive region.

The source S, the active region A, and the drain D of the transistor TR1 may be formed from the semiconductor pattern. In FIG. 5, a portion of the signal transmission region SCL formed from the semiconductor pattern is illustrated. In one or more embodiments, the signal transmission region SCL may be connected to the drain D of the transistor TR1 when viewed from above the plane.

The first to fifth insulating layers 10, 20, 30, 40, and 50 may be located on the buffer layer BFL. The first to fifth insulating layers 10, 20, 30, 40, and 50 may be inorganic layers or organic layers.

The first insulating layer 10 may be located on the buffer layer BFL. The first insulating layer 10 may cover the source S, the active region A, and the drain D of the transistor TR1 and the signal transmission region SCL that are located on the buffer layer BFL. A gate G of the transistor TR1 may be located on the first insulating layer 10. The second insulating layer 20 may be located on the first insulating layer 10 and may cover the gate G. The electrode EE may be located on the second insulating layer 20. The third insulating layer 30 may be located on the second insulating layer 20 and may cover the electrode EE.

The first connecting electrode CNE1 may be located on the third insulating layer 30. The first connecting electrode CNE1 may be connected to the signal transmission region SCL through a contact hole CNT-1 penetrating the first to third insulating layers 10, 20, and 30. The fourth insulating layer 40 may be located on the third insulating layer 30, and may cover the first connecting electrode CNE1. The fourth insulating layer 40 may be an organic layer.

The second connecting electrode CNE2 may be located on the fourth insulating layer 40. The second connecting electrode CNE2 may be connected to the first connecting electrode CNE1 through a contact hole CNT-2 penetrating the fourth insulating layer 40. The fifth insulating layer 50 may be located on the fourth insulating layer 40, and may cover the second connecting electrode CNE2. The fifth insulating layer 50 may be an organic layer.

The display element layer DP-OLED may be located on the circuit element layer DP-CL. The display element layer DP-OLED may include a light-emitting element ED, a sacrificial pattern SP, a pixel-defining layer PDL, the barrier wall PW, the inorganic pattern IP, and dummy patterns DMP.

The light-emitting element ED may include an anode AE (e.g., a first electrode), an emission pattern EP, and a cathode CE (e.g., a second electrode).

The anode AE may be located on the fifth insulating layer 50 of the circuit element layer DP-CL. The anode AE may be a transmissive electrode, a transflective electrode, or a reflective electrode. The anode AE may be connected to the second connecting electrode CNE2 by a connection contact hole CNT-3 penetrating the fifth insulating layer 50. Accordingly, the anode AE may be electrically connected to the signal transmission region SCL through the first and second connecting electrodes CNE1 and CNE2, and may be electrically connected to a corresponding circuit element. The anode AE may include a single-layer structure or a multi-layer structure. The anode AE may include a plurality of layers including ITO and Ag. For example, the anode AE may include a layer including ITO (hereinafter, referred to as the lower ITO layer), a layer that is located on the lower ITO layer and that includes Ag (hereinafter, referred to as the Ag layer), and a layer that is located on the Ag layer and that includes ITO (hereinafter, referred to as the upper ITO layer).

The sacrificial pattern SP may be located between the anode AE and the pixel-defining layer PDL. A sacrificial opening OP-S that exposes a portion of the upper surface of the anode AE may be defined in the sacrificial pattern SP. The sacrificial opening OP-S may overlap a light-emitting opening OP-E that will be described below.

The pixel-defining layer PDL may be located on the fifth insulating layer 50 of the circuit element layer DP-CL. The pixel-defining layer PDL may have the light-emitting opening OP-E defined therein. The light-emitting opening OP-E may correspond to the anode AE, and the pixel-defining layer PDL may expose at least a portion of the anode AE through the light-emitting opening OP-E.

The light-emitting opening OP-E may correspond to the sacrificial opening OP-S of the sacrificial pattern SP. The upper surface of the anode AE may be spaced apart from the pixel-defining layer DPL on the section with the sacrificial pattern SP therebetween. Accordingly, damage to the anode AE in a process of forming the light-emitting opening OP-E may be reduced or prevented.

When viewed from above the plane, the area of the light-emitting opening OP-E may be smaller than the area of the sacrificial opening OP-S. That is, the inner surface of the pixel-defining layer PDL that defines the light-emitting opening OP-E may be closer to the center of the anode AE than the inner surface of the sacrificial pattern SP that defines the sacrificial opening OP-S. However, without being limited thereto, the inner surface of the sacrificial pattern SP that defines the sacrificial opening OP-S may be substantially aligned with the inner surface of the pixel-defining layer PDL that defines the light-emitting opening OP-E. In this case, the emissive region PXA may be a region of the anode AE exposed from the corresponding sacrificial opening OP-S.

The pixel-defining layer PDL may include an inorganic insulating material. For example, the pixel-defining layer PDL may include silicon nitride SiNₓ. The pixel-defining layer PDL may be located between the anode AE and the barrier wall PW and may block electrical connection between the anode AE and the barrier wall PW.

The emission pattern EP may be located on the anode AE. The emission pattern EP may include an emissive layer including a luminescent material. The emission pattern EP may further include a hole injection layer (HIL) and a hole transport layer (HTL) that are located between the anode AE and the emissive layer, and may further include an electron transport layer (ETL) and an electron injection layer (EIL) that are located on the emissive layer. The emission pattern EP may be referred to as an “organic layer” or an “intermediate layer.”

The emission pattern EP may be subjected to patterning by a tip portion defined in the barrier wall PW. The emission pattern EP may be located in the sacrificial opening OP-S, the light-emitting opening OP-E, and a barrier wall opening OP-P. The emission pattern EP may cover a portion of the upper surface of the pixel-defining layer PDL exposed from the barrier wall opening OP-P.

The cathode CE may be located on the emission pattern EP. The cathode CE may be subjected to patterning by the tip portion defined in the barrier wall PW. At least a portion of the cathode CE may be located in the barrier wall opening OP-P. The cathode CE may contact the side surface of the first barrier wall layer L1. For example, the cathode CE may contact a first sub-barrier wall layer L11 of the first barrier wall layer L1, and may extend to a portion making contact with the inorganic pattern IP along the side surface S_L11 of the first sub-barrier wall layer L11 of the first barrier wall layer L1. However, this is illustrative, and a portion of the cathode CE may be deposited on a side surface S_L12 of a second sub-barrier wall layer L12 of the first barrier wall layer L1, and/or on the lower surface of a second barrier wall layer L2.

The cathode CE may have conductivity. As long as the cathode CE is capable of having conductivity, the cathode CE may be formed of various materials, such as metal, transparent conductive oxide (TCO), or a conductive polymer material. For example, the cathode CE may include silver (Ag), magnesium (Mg), lead (Pb), copper (Cu), or a compound thereof.

The barrier wall PW may be located on the pixel-defining layer PDL. The barrier wall PW may have the barrier wall opening OP-P defined therein. The barrier wall opening OP-P may correspond to (e.g., may overlap) the light-emitting opening OP-E, and may expose at least a portion of the anode AE.

The barrier wall PW may have an undercut shape on the section. The barrier wall PW may include multiple layers sequentially stacked one above another, and at least one layer among the multiple layers may be recessed when compared to the other layers. Accordingly, the barrier wall PW may include the tip portion.

The barrier wall PW may include the first barrier wall layer L1 and the second barrier wall layer L2. The first barrier wall layer L1 may be located on the pixel-defining layer PDL, and the second barrier wall layer L2 may be located on the first barrier wall layer L1. The first barrier wall layer L1 may include the first sub-barrier wall layer L11 located on the pixel-defining layer PDL, and may include the second sub-barrier wall layer L12 located on the first sub-barrier wall layer L11. As illustrated in FIG. 5, the thickness of the first barrier wall layer L1, which includes the first sub-barrier wall layer L11 and the second sub-barrier wall layer L12, may be greater than the thickness of the second barrier wall layer L2. However, the present disclosure is not limited thereto.

The inorganic pattern IP may be located in the first barrier wall layer L1. In detail, the inorganic pattern IP may be located between the first sub-barrier wall layer L11 and the second sub-barrier wall layer L12. The inorganic pattern IP may protrude into the barrier wall opening OP-P further than the first barrier wall layer L1, and the second barrier wall layer L2 may protrude into the barrier wall opening OP-P further than the first barrier wall layer L1. That is, the first sub-barrier wall layer L11 and the second sub-barrier wall layer L12 may be relatively recessed with respect to the emissive region PXA when compared to the inorganic pattern IP and/or the second barrier wall layer L2. The first sub-barrier wall layer L11 and the second sub-barrier wall layer L12 may be undercut with respect to the inorganic pattern IP and/or the second barrier wall layer L2. The portion of the second barrier wall layer L2 that protrudes from the first barrier wall layer L1 toward the emissive region PXA may be defined as the tip portion in the barrier wall PW.

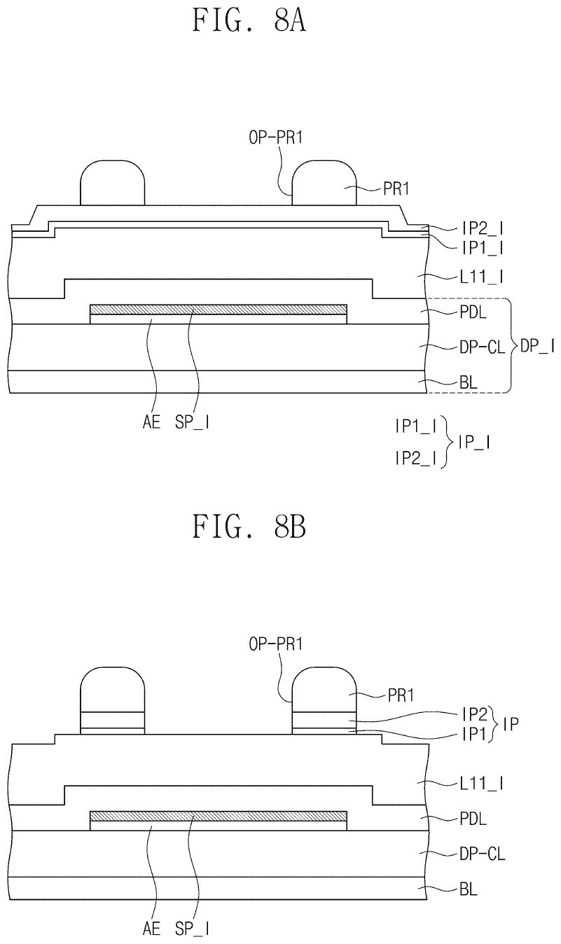

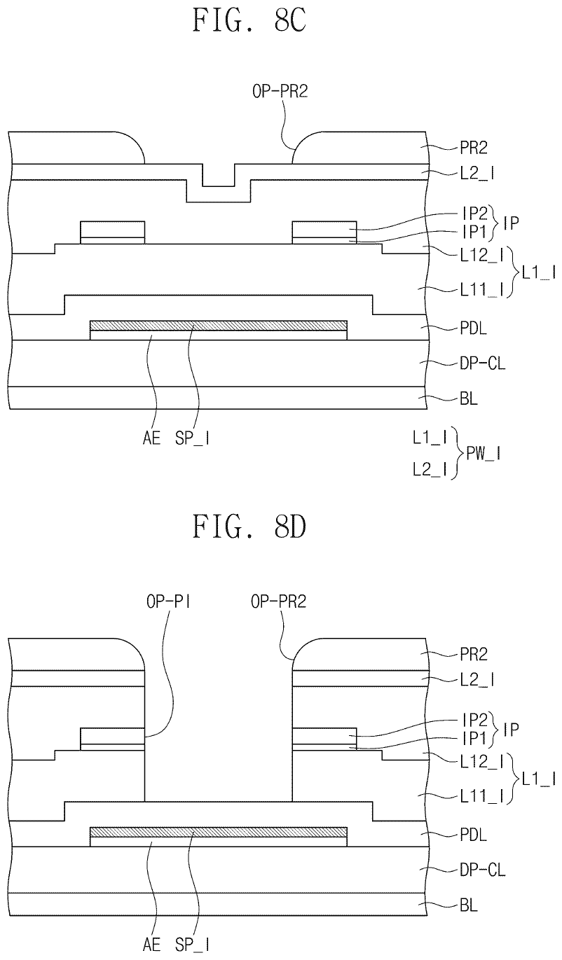

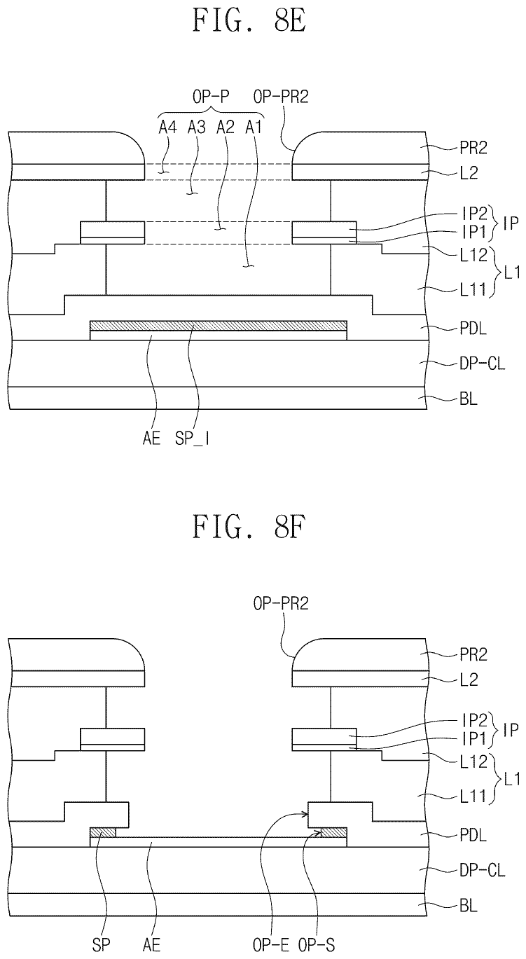

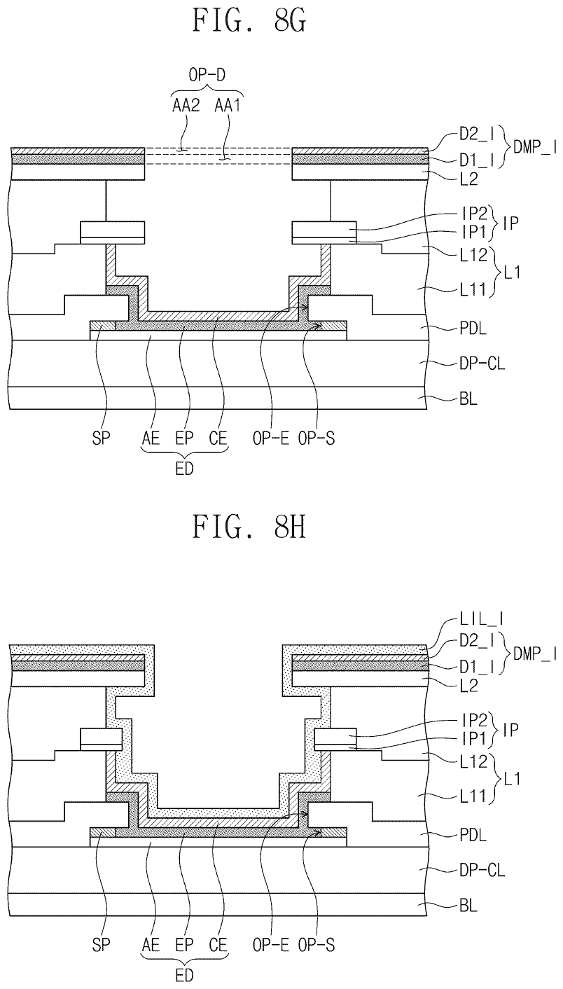

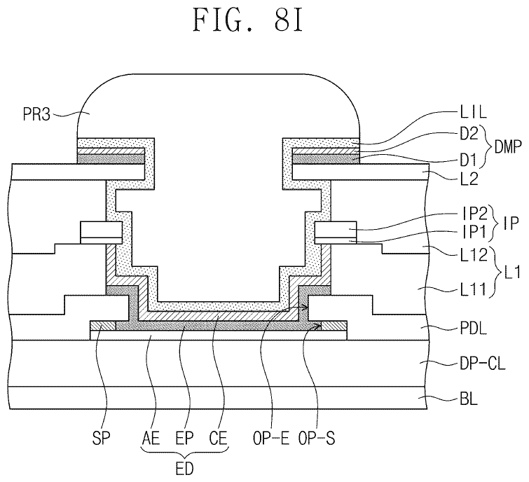

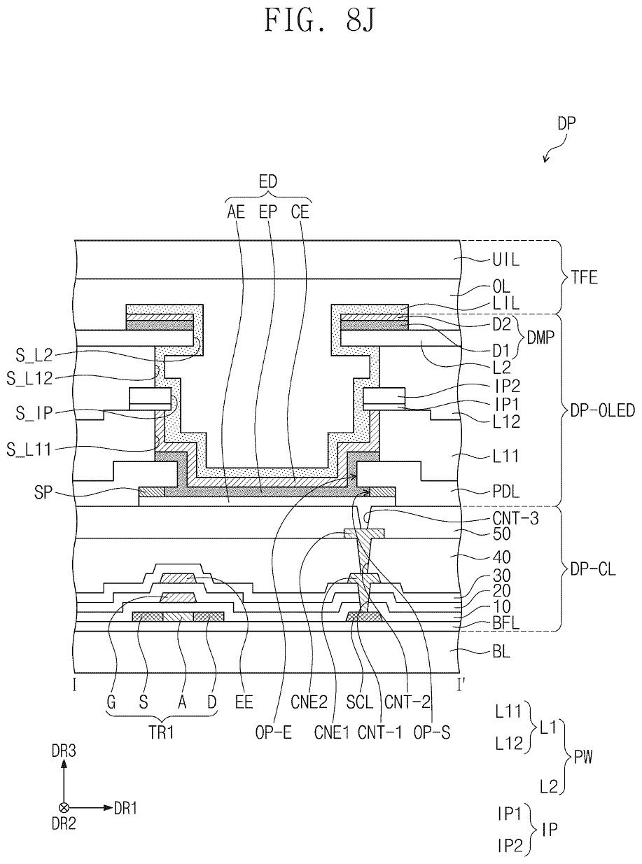

The barrier wall opening OP-P defined in the barrier wall PW may include a first region A1 (refer to FIG. 8E), a second region A2 (refer to FIG. 8E), a third region A3 (refer to FIG. 8E), and a fourth region A4 (refer to FIG. 8E). The first region A1 may be defined by the side surface S_L11 of the first sub-barrier wall layer L11, and the second region A2 may be defined by the side surface S_IP of the inorganic pattern IP. The third region A3 may be defined by the side surface S_L12 of the second sub-barrier wall layer L12, and the fourth region A4 may be defined by the side surface S_L2 of the second barrier wall layer L2. The first to fourth regions A1, A2, A3, and A4 may be openings integrally formed in the thickness direction of the base layer BL (e.g., the third direction DR3). The fourth region A4 of the barrier wall opening OP-P may be a region that defines the tip portion.

In plan view, the side surface S_L2 of the second barrier wall layer L2 and the side surface S_IP of the inorganic pattern IP may be closer to the center of the anode AE than the side surface S_L11 of the first sub-barrier wall layer L11 and the side surface S_L12 of the second sub-barrier wall layer L12. The side surface S_L11 of the first sub-barrier wall layer L11 and the side surface S_L12 of the second sub-barrier wall layer L12 may be recessed in a direction away from the center of the anode AE when compared to the side surface S_L2 of the second barrier wall layer L2 and the side surface S_IP of the inorganic pattern IP.

The first to fourth regions A1, A2, A3, and A4 may have different widths. For example, the widths of the first region A1 and the third region A3 may be greater than the widths of the second region A2 and the fourth region A4. Although FIG. 5 illustrates an example that the first region A1 and the third region A3 have the same width, the present disclosure is not limited thereto. For example, the width of the first region A1 may be greater or smaller than the width of the third region A3.

However, the inorganic pattern IP protruding further toward (e.g., into) the barrier wall opening OP-P (e.g., toward a center of the barrier wall opening OP-P in plan view) when compared to the first barrier wall layer L1 is illustrative, and the present disclosure is not limited thereto. For example, when the first sub-barrier wall layer L11 and the second sub-barrier wall layer L12 are lightly etched portions (portions of the emissive region that are not in sufficient contact with an etchant), the first sub-barrier wall layer L11 and the second sub-barrier wall layer L12 may be relatively recessed with respect to the emissive region PXA when compared to the second barrier wall layer L2, but may not be relatively recessed when compared to the inorganic pattern IP. That is, the side surfaces S_L11, S_IP, and S_L12 of the first sub-barrier wall layer L11, the inorganic pattern IP, and the second sub-barrier wall layer L12 may be aligned, and the first sub-barrier wall layer L11, the inorganic pattern IP, and the second sub-barrier wall layer L12 may be undercut with respect to the second barrier wall layer L2. In this case, the first to third regions A1, A2, and A3 may have the same width, and the fourth region A4 may have a smaller width than the first to third regions A1, A2, and A3.

Each of the first barrier wall layer L1 and the second barrier wall layer L2 may include a conductive material. For example, the conductive material may include metal, transparent conductive oxide (TCO), or a combination thereof. For example, the metal may include gold (Au), silver (Ag), aluminum (AI), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

Although FIG. 5 illustrates an example that the side surface S_L11 of the first sub-barrier wall layer L11, the side surface S_IP of the inorganic pattern IP, the side surface S_L12 of the second sub-barrier wall layer L12, and the side surface S_L2 of the second barrier wall layer L2 are substantially perpendicular to the upper surface of the pixel-defining layer PDL, the present disclosure is not limited thereto. For example, the barrier wall PW may have a tapered shape or an inverted tapered shape.

The barrier wall PW may receive a second drive voltage ELVSS. Accordingly, the cathode CE may be electrically connected to the barrier wall PW, and may receive the second drive voltage ELVSS.

The inorganic pattern IP may have a smaller width in one direction than the barrier wall PW. For example, the inorganic pattern IP may have a smaller width in the first direction DR1 than the barrier wall PW. The inorganic pattern IP may include a first inorganic pattern IP1 located on the first sub-barrier wall layer L11, and a second inorganic pattern IP2 located on the first inorganic pattern IP1. The second inorganic pattern IP2 may be covered by the second sub-barrier wall layer L12. The first inorganic pattern IP1 may have a smaller thickness than the second inorganic pattern IP2.

The first inorganic pattern IP1 may include transparent conductive oxide (TCO), and the second inorganic pattern IP2 may include an insulating material. For example, the first inorganic pattern IP1 may include at least one of indium tin oxide (ITO), indium zinc oxide (IZO), indium gallium zinc oxide (IGZO), zinc oxide (ZnO), or indium oxide (In₂O₃), and the second inorganic pattern IP2 may include at least one of SiOₓ or SiNₓ.

The dummy patterns DMP may be located on the barrier wall PW. The dummy patterns DMP may include a first dummy pattern D1 and a second dummy pattern D2. The first and second dummy patterns D1 and D2 may be sequentially stacked on the upper surface of the second barrier wall layer L2 of the barrier wall PW in the third direction DR3.

The first dummy pattern D1 may include an organic material. For example, the first dummy pattern D1 may include the same material as the emission pattern EP. The first dummy pattern D1 may be concurrently or substantially simultaneously formed with the emission pattern EP through one process, and may be separated from the emission pattern EP by the undercut shape of the barrier wall PW.

The second dummy pattern D2 may include a conductive material. For example, the second dummy pattern D2 may include the same material as the cathode CE. The second dummy pattern D2 may be concurrently or substantially simultaneously formed with the cathode CE through one process, and may be separated from the cathode CE by the undercut shape of the barrier wall PW.

A dummy opening OP-D may be defined in the dummy patterns DMP. The dummy opening OP-D may correspond to the light-emitting opening OP-E. The dummy opening OP-D may include first and second regions AA1 and AA2 (refer to FIG. 8G) that are sequentially arranged in the third direction DR3. The first region AA1 (refer to FIG. 8G) of the dummy opening OP-D may be defined by the inner surface of the first dummy pattern D1, and the second region AA2 (refer to FIG. 8G) of the dummy opening OP-D may be defined by the inner surface of the second dummy pattern D2. Each of the first and second dummy patterns D1 and D2, when viewed from above the plane, may have a closed-line shape surrounding the emissive region PXA.

Although FIG. 5 illustrates an example that the inner surfaces of the first and second dummy patterns D1 and D2 are aligned with the side surface S_L2 of the second barrier wall layer L2, the present disclosure is not limited thereto, and the first and second dummy patterns D1 and D2 may cover the side surface S_L2 of the second barrier wall layer L2.

The thin film encapsulation layer TFE may be located on the display element layer DP-OLED. The thin film encapsulation layer TFE may include a lower inorganic encapsulation pattern LIL, an organic encapsulation film OL, and an upper inorganic encapsulation film UIL.

The lower inorganic encapsulation pattern LIL may correspond to the light-emitting opening OP-E. For example, one portion of the lower inorganic encapsulation pattern LIL may be located in the barrier wall opening OP-P, and another portion of the lower inorganic encapsulation pattern LIL may be located on the barrier wall PW. The portion of the lower inorganic encapsulation pattern LIL located in the barrier wall opening OP-P may be located on the cathode CE, and may cover the cathode CE. In this case, the inorganic pattern IP may make direct contact with the lower inorganic encapsulation patter LIL.

The organic encapsulation film OL may cover the lower inorganic encapsulation pattern LIL, and may provide a flat upper surface. The upper inorganic encapsulation film UIL may be located on the organic encapsulation film OL.

The lower inorganic encapsulation pattern LIL and the upper inorganic encapsulation film UIL may protect the display element layer DP-OLED from moisture/oxygen, and the organic encapsulation film OL may protect the display element layer DP-OLED from foreign matter, such as dust particles.

According to the present disclosure, because the inorganic pattern IP is coupled by making direct contact with the lower inorganic encapsulation pattern LIL, the coupling force of the lower inorganic encapsulation pattern LIL may be improved, and the sealing ability of the lower inorganic encapsulation pattern LIL to protect the display element layer DP-OLED may be improved. Accordingly, pixel defects (dark spots, pixel shrinkage, or the like) caused by foreign matter introduced from the side surface of the lower inorganic encapsulation pattern LIL may be reduced or eliminated, and as a wet etch region is increased in an etching operation of the lower encapsulation inorganic pattern LIL, the mass productivity of the display panel DP may be improved.

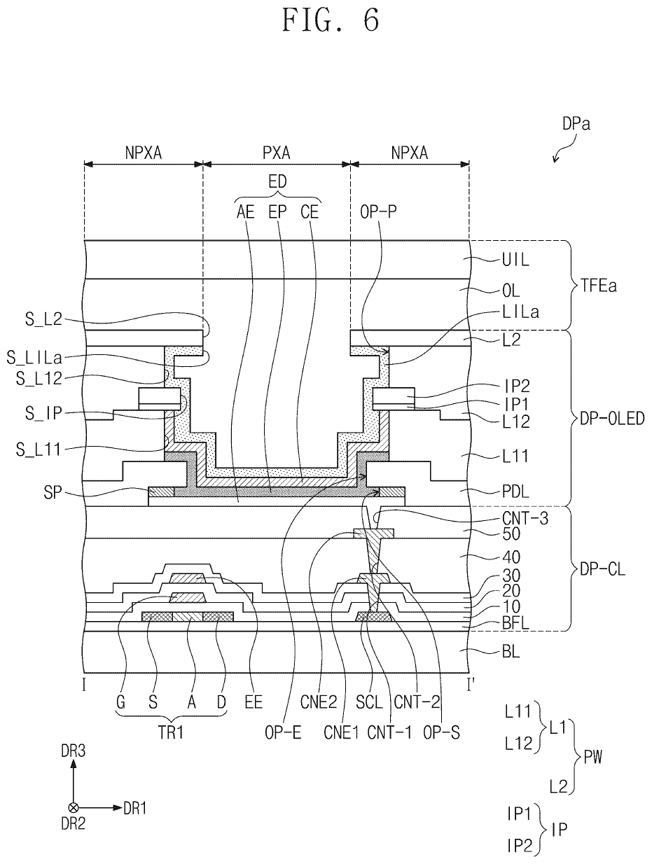

FIG. 6 is a sectional view of a display panel taken along the line I-I′ of FIG. 3 according to one or more embodiments of the present disclosure. In describing FIG. 6, components identical or similar to the components described with reference to FIG. 5 will be assigned with identical or similar reference numerals, and repetitive descriptions will be omitted.

Referring to FIG. 6, the display panel DPa may include a base layer BL, a circuit element layer DP-CL, a display element layer DP-OLED, and a thin film encapsulation layer TFEa. The thin film encapsulation layer TFEa may include a lower inorganic encapsulation pattern LILa, an organic encapsulation film OL, and an upper inorganic encapsulation film UIL.

The lower inorganic encapsulation pattern LILa may be located in a barrier wall opening OP-P. For example, unlike the lower inorganic encapsulation pattern LIL of FIG. 5, the lower inorganic encapsulation pattern LILa of FIG. 6 may not be located on (e.g., directly above) a barrier wall PW. The lower inorganic encapsulation pattern LILa may be formed by removing the dummy patterns DMP of FIG. 5 through wet etching, and thereafter dry etching, a portion of the lower inorganic encapsulation pattern LIL located on the barrier wall.

According to the present disclosure, because an inorganic pattern IP is coupled by making direct contact with the lower inorganic encapsulation pattern LILa, the coupling force of the lower inorganic encapsulation pattern LILa may be improved, and the sealing ability of the lower inorganic encapsulation pattern LILa to protect the display element layer DP-OLED may be improved. Accordingly, even though a portion of the lower inorganic encapsulation pattern LILa formed on the barrier wall PW is etched and removed, the sealing ability of the lower inorganic encapsulation pattern LILa may be improved.

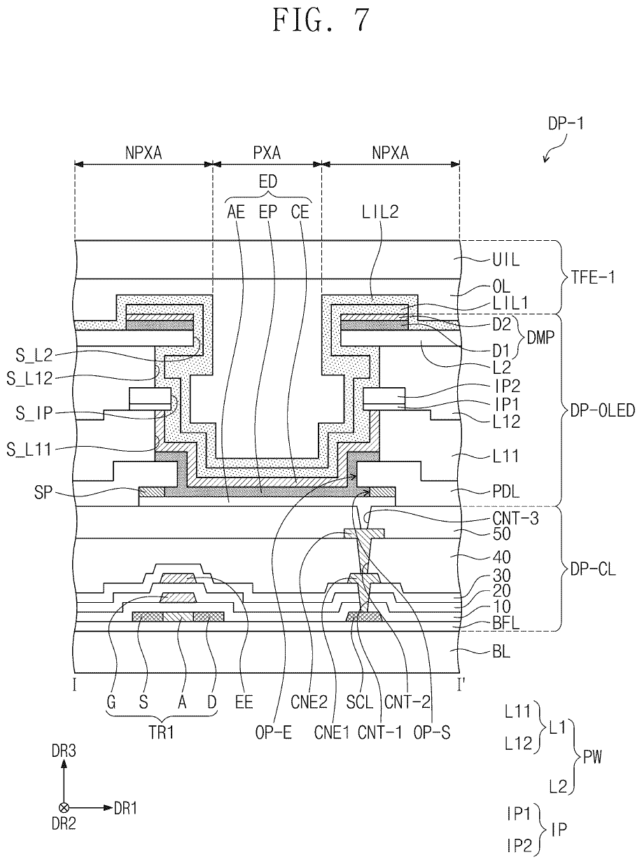

FIG. 7 is a sectional view of a display panel taken along the line I-I′ of FIG. 3 according to one or more embodiments of the present disclosure. In describing FIG. 7, components identical or similar to the components described with reference to FIG. 5 will be assigned with identical or similar reference numerals, and repetitive descriptions will be omitted.

Referring to FIG. 7, the display panel DP-1 may include a base layer BL, a circuit element layer DP-CL, a display element layer DP-OLED, and a thin film encapsulation layer TFE-1. The thin film encapsulation layer TFE-1 may include a first lower inorganic encapsulation pattern LIL1, a second lower inorganic encapsulation pattern LIL2, an organic encapsulation film OL, and an upper inorganic encapsulation film UIL. The first lower inorganic encapsulation pattern LIL1 of the thin film encapsulation layer TFE-1 may be substantially the same as the lower inorganic encapsulation pattern LIL of FIG. 5. That is, the thin film encapsulation layer TFE-1 of FIG. 7 may further include the second lower inorganic encapsulation pattern LIL2 in the thin film encapsulation layer TFE of FIG. 5.

The second lower inorganic encapsulation pattern LIL2 may be located on the first lower inorganic encapsulation pattern LIL1, and may cover the upper surface and the side surface of the first lower inorganic encapsulation pattern LIL1, the side surfaces of dummy patterns DMP, and the upper surface of a barrier wall PW. The second lower inorganic encapsulation pattern LIL2 may include the same material as the first lower inorganic encapsulation pattern LIL1. The second lower inorganic encapsulation pattern LIL2 may block foreign matter introduced from the side surface of the first lower inorganic encapsulation pattern LIL1.

Referring to FIGS. 5 and 7, unlike the display panel DP-1 of FIG. 7, the display panel DP of FIG. 5 may not include the second lower inorganic encapsulation pattern LIL2. Because an inorganic pattern IP is coupled by making direct contact with the first lower inorganic encapsulation pattern LIL1, the coupling force of the first lower inorganic encapsulation pattern LIL1 may be improved, and the sealing ability of the first lower inorganic encapsulation pattern LIL1 to protect the display element layer DP-OLED may be improved. Accordingly, the first lower inorganic encapsulation pattern LIL1 itself may block foreign matter introduced from the side surface of the first lower inorganic encapsulation pattern LIL1, and thus the second lower inorganic encapsulation pattern LIL2 may be omitted.

FIGS. 8A to 8J are sectional views illustrating some of the operations of a display panel manufacturing method according to one or more embodiments of the present disclosure. In describing FIGS. 8A to 8J, components identical/similar to the components described with reference to FIGS. 1 to 5 will be assigned with identical/similar reference numerals, and repetitive descriptions will be omitted.

The display panel manufacturing method according to the present disclosure may include an operation of providing a preliminary display panel including a base layer, and a pixel-defining layer located on the base layer, an operation of depositing a first preliminary sub-barrier wall layer on the preliminary display panel, an operation of depositing an inorganic layer on the first preliminary sub-barrier wall layer, an operation of forming an inorganic pattern by etching the inorganic layer, an operation of depositing a second preliminary sub-barrier wall layer and a preliminary metal barrier wall layer on the first preliminary sub-barrier wall layer and the inorganic pattern, and an operation of forming a barrier wall defining a barrier wall opening by etching the first preliminary sub-barrier wall layer, the second preliminary sub-barrier wall layer, and the preliminary metal barrier wall layer.

Hereinafter, a method of forming one light-emitting element ED and a lower inorganic encapsulation pattern LIL, an organic encapsulation film OL, and an upper inorganic encapsulation film UIL that cover the light-emitting element ED will be described with reference to FIGS. 8A to 8J. A display panel formed through the method illustrated in FIGS. 8A to 8J may correspond to the display panel DP of FIG. 5.

Referring to FIG. 8A, the display panel manufacturing method may include the operation of providing the preliminary display panel DP_I, the operation of depositing the first preliminary sub-barrier wall layer L11_I, and the operation of depositing the inorganic layer IP_I.

The preliminary display panel DP_I may include the base layer BL, a circuit element layer DP-CL, an anode AE, a preliminary sacrificial pattern SP_I, and the pixel-defining layer PDL.

The circuit element layer DP-CL may be formed through a conventional circuit element manufacturing process of forming an insulating layer, a semiconductor layer, and a conductive layer by coating, deposition, or the like, and forming a semiconductor pattern, a conductive pattern, and a signal line by selectively making the insulating layer, the semiconductor layer, and the conductive layer subject to patterning by photolithography and etching processes.

The anode AE and the preliminary sacrificial pattern SP_I may be formed by the same patterning process. The pixel-defining layer PDL may be located on the base layer BL. The pixel-defining layer PDL may cover both the anode AE and the preliminary sacrificial pattern SP_I.

The first preliminary sub-barrier wall layer L11_I may be deposited on the preliminary display panel DP_I. The first preliminary sub-barrier wall layer L11_I may be formed by a process of depositing a conductive material. The first preliminary sub-barrier wall layer L11_I may include metal, transparent conductive oxide (TCO), or a combination thereof. For example, the metal may include gold (Au), silver (Ag), aluminum (Al), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide.

The inorganic layer IP_I may be deposited on the first preliminary sub-barrier wall layer L11_I. The operation of depositing the inorganic layer IP_I may include an operation of depositing a first inorganic layer IP1_I on the first preliminary sub-barrier wall layer L11_I, and an operation of depositing a second inorganic layer IP2_I on the first inorganic layer IP1_I. The first inorganic layer IP1_I and the second inorganic layer IP2_I may be formed by a process of depositing a conductive material. In this case, the second inorganic layer IP2_I may be deposited to be thicker than the first inorganic layer IP1_I.

The first inorganic layer IP1_I may include transparent conductive oxide (TCO). For example, the first inorganic layer IP1_I may include at least one of indium tin oxide (ITO), indium zinc oxide (IZO), indium gallium zinc oxide (IGZO), zinc oxide (ZnO), or indium oxide (In₂O₃). The second inorganic layer IP2_I may include an insulating material. For example, the second inorganic layer IP2_I may include at least one of SiOₓ or SiNₓ.

The display panel manufacturing method may include an operation of forming a first photoresist layer PR1 on the second inorganic layer IP2_I. The first photoresist layer PR1 may be formed by forming a preliminary photoresist layer on the second inorganic layer IP2_I, and thereafter making the preliminary photoresist layer subject to patterning using a photo mask. Through the patterning process, a first photo opening OP-PR1 overlapping the anode AE may be formed in the first photoresist layer PR1.

Referring to FIG. 8B, the display panel manufacturing method may include the operation of forming the inorganic pattern IP by etching the inorganic layer IP_I (refer to FIG. 8A). The inorganic pattern IP may overlap the first photoresist layer PR1 (e.g., in plan view).

The operation of forming the inorganic pattern IP may include an operation of forming a first inorganic pattern IP1 by etching the first inorganic layer IP1_I, and an operation of forming a second inorganic pattern IP2 by etching the second inorganic layer IP2_I. For example, in the operation of forming the inorganic pattern IP, the first inorganic pattern IP1 and the second inorganic pattern IP2 may be formed by dry etching the second inorganic layer IP2_I using the first photoresist layer PR1 as a mask, and thereafter wet etching the first inorganic layer IP1_I using the first photoresist layer PR1 as a mask. In this case, the second inorganic layer IP2_I located on the first inorganic layer IP1_I may be first etched to form the second inorganic pattern IP2, and thereafter the first inorganic layer IP1_I may be etched to form the first inorganic pattern IP1. The first inorganic pattern IP1 and the second inorganic pattern IP2 may form the inorganic pattern IP.

Referring to FIG. 8C, the display panel manufacturing method may include the operation of depositing the second preliminary sub-barrier wall layer L12_I and the second preliminary barrier wall layer L2_I on the first preliminary sub-barrier wall layer L11_I and on the inorganic pattern IP after removing the first photoresist layer PR1 (refer to FIG. 8B). The second preliminary barrier wall layer L2_I may be referred to as the preliminary metal barrier wall layer L2_I.

The second preliminary sub-barrier wall layer L12_I may be formed by a process of depositing a conductive material on the first preliminary sub-barrier wall layer L11_I and the inorganic pattern IP, and the second preliminary barrier wall layer L2_I may be formed by a process of depositing a conductive material on the second preliminary sub-barrier wall layer L12_I.

The second preliminary sub-barrier wall layer L12_I and the second preliminary barrier wall layer L2_I may include metal, transparent conductive oxide (TCO), or a combination thereof. For example, the metal may include gold (Au), silver (Ag), aluminum (AI), magnesium (Mg), lithium (Li), molybdenum (Mo), titanium (Ti), copper (Cu), or an alloy. The transparent conductive oxide may include indium tin oxide (ITO), indium zinc oxide (IZO), zinc oxide, indium oxide, indium gallium oxide, indium gallium zinc oxide (IGZO), or aluminum zinc oxide. The first preliminary barrier wall layer L1_I and the second preliminary barrier wall layer L2_I may form a preliminary barrier wall PW_I.

The display panel manufacturing method may include an operation of forming a second photoresist layer PR2 on the second preliminary barrier wall layer L2_1. The second photoresist layer PR2 may be formed by forming a preliminary photoresist layer on the second preliminary barrier wall layer L2_I, and thereafter by making the preliminary photoresist layer subject to patterning using a photo mask. Through the patterning process, a second photo opening OP-PR2 overlapping the anode AE may be formed in the second photoresist layer PR2.

Referring to FIGS. 8D and 8E, the display panel manufacturing method may include the operation of forming the barrier wall PW having the barrier wall opening OP-P defined therein by etching the first preliminary sub-barrier wall layer L11_I, the second preliminary sub-barrier wall layer L12_I, and the second preliminary barrier wall layer L2_I such that the barrier wall PW is formed from the preliminary barrier wall PW_I (refer to FIG. 8C). The operation of forming the barrier wall PW may include an operation of firstly etching the first preliminary sub-barrier wall layer L11_I, the second preliminary sub-barrier wall layer L12_I, and the second preliminary barrier wall layer L2_I, and an operation of forming a first sub-barrier wall layer L11, a second sub-barrier wall layer L12, and a second barrier wall layer L2 by secondly etching the first preliminary sub-barrier wall layer L11_I and the second preliminary sub-barrier wall layer L12_I. The second barrier wall layer L2 may be referred to as the metal barrier wall layer L2.

As illustrated in FIG. 8D, the operation of firstly etching the first preliminary sub-barrier wall layer L11_I, the second preliminary sub-barrier wall layer L12_I, and the second preliminary barrier wall layer L2_I may include an operation of forming a preliminary barrier wall opening OP-PI in the preliminary barrier wall PW_I (refer to FIG. 8C) by dry etching the first preliminary sub-barrier wall layer L11_I, the second preliminary sub-barrier wall layer L12_I, and the second preliminary barrier wall layer L2_I using the second photoresist layer PR2 as a mask.

The first dry etching process may be performed in an etching environment in which the etch selectivity between the first preliminary sub-barrier wall layer L11_I, the second preliminary sub-barrier wall layer L12_I, and the second preliminary barrier wall layer L2_I is substantially the same. Accordingly, the inner surface of the first preliminary sub-barrier wall layer L11_I, the inner surface of the second preliminary sub-barrier wall layer L12_I, and the inner surface of the second preliminary barrier wall layer L2_I that define the preliminary barrier wall opening OP-PI may be substantially aligned.

As illustrated in FIGS. 8D and 8E, the operation of secondly etching the first preliminary sub-barrier wall layer L11_I and the second preliminary sub-barrier wall layer L12_I may include an operation of forming the barrier wall opening OP-P from the preliminary barrier wall opening OP-PI by wet etching the first preliminary sub-barrier wall layer L11_I and the second preliminary sub-barrier wall layer L12_I using the second photoresist layer PR2 as a mask.

The operation of forming the first sub-barrier wall layer L11, the second sub-barrier wall layer L12, and the second barrier wall layer L2 by secondly etching the first preliminary sub-barrier wall layer L11_I and the second preliminary sub-barrier wall layer L12_I may include an operation of etching the first and second preliminary sub-barrier wall layers L11_I and L12_I such that the inorganic pattern IP protrudes toward the barrier wall opening OP-P when compared to the first and second sub-barrier wall layers L11 and L12.

The barrier wall opening OP-P may include a first region A1, a second region A2, a third region A3, and a fourth region A4 sequentially located in the thickness direction (that is, the third direction DR3). The side surface of the first sub-barrier wall layer L11 may define the first region A1 of the barrier wall opening OP-P, and the side surface of the inorganic pattern IP may define the second region A2 of the barrier wall opening OP-P. The side surface of the second sub-barrier wall layer L12 may define the third region A3 of the barrier wall opening OP-P, and the side surface of the second barrier wall L2 may define the fourth region A4 of the barrier wall opening OP-P.

The second wet etching process may be performed in an environment in which the etch selectivity between the first and second preliminary sub-barrier wall layers L11_I and L12_I and the second preliminary barrier wall layer L2_I is high. Accordingly, the second barrier wall layer L2 may have a shape further protruding toward the barrier wall opening OP-P when compared to the first and second sub-barrier wall layers L11 and L12. For example, because the etch rate of the first and second preliminary sub-barrier wall layers L11_I and L12_I by an etchant is higher than the etch rate of the second preliminary barrier wall layer L2_I by the etchant, the first and second preliminary sub-barrier wall layers L11_I and L12_I may be mainly etched (e.g., may be etched to a greater degree). Accordingly, the side surfaces of the first and second sub-barrier wall layers L11 and L12 may be further inwardly recessed when compared to the side surface of the second barrier wall layer L2. A tip portion may be formed in the barrier wall PW by the portion of the second barrier wall layer L2 that protrudes further when compared to the first barrier wall layer L1.

The second wet etching process may be performed in an environment in which the etch selectivity between the first and second preliminary sub-barrier wall layers L11_I and L12_I and the inorganic pattern IP is high. Accordingly, the inorganic pattern IP may have a shape protruding further toward the barrier wall opening OP-P when compared to the first and second sub-barrier wall layers L11 and L12. For example, because the etch rate of the first and second preliminary sub-barrier wall layers L11_I and L12_I by an etchant is higher than the etch rate of the inorganic pattern IP by the etchant, the first and second preliminary sub-barrier wall layers L11_I and L12_I may be mainly etched. Accordingly, the side surfaces of the first and second sub-barrier wall layers L11 and L12 may be recessed further inward when compared to the side surface of the inorganic pattern IP.

However, the inorganic pattern IP protruding further toward the barrier wall opening OP-P when compared to the first and second sub-barrier wall layers L11 and L12 is illustrative, and the present disclosure is not limited thereto. For example, when the first and second preliminary sub-barrier wall layers L11_I and L12_I are lightly etched portions (portions of an emissive region that are not in sufficient contact with an etchant), the first sub-barrier wall layer L11 and the second sub-barrier wall layer L12 may not be relatively recessed when compared to the inorganic pattern IP. That is, the side surfaces of the first sub-barrier wall layer L11, the inorganic pattern IP, and the second sub-barrier wall layer L12 may be aligned, and the first sub-barrier wall layer L11, the inorganic pattern IP, and the second sub-barrier wall layer L12 may be undercut with respect to the second barrier wall layer L2. In this case, the first to third regions A1, A2, and A3 may have substantially the same width, and the fourth region A4 may have a smaller width than the first to third regions A1, A2, and A3.

In one or more embodiments of the present disclosure, the operation of forming the barrier wall opening OP-P may include an operation of concurrently or substantially simultaneously forming barrier wall openings OP-P corresponding to the first to third emissive regions PXA-R, PXA-G, and PXA-B (refer to FIG. 4). In one or more embodiments of the present disclosure, the operation of forming the barrier wall opening OP-P may include an operation of forming only the barrier wall opening OP-P corresponding to the first emissive region PXA-R. For example, after the barrier wall opening OP-P corresponding to the first emissive region PXA-R is formed, and then the first light-emitting element is formed through a subsequent process, the barrier wall opening OP-P corresponding to the second emissive region PXA-G may be formed. In addition, through a subsequent process, the second light-emitting element may be formed, and the barrier wall opening OP-P corresponding to the third emissive region PXA-B may be formed.

Referring to FIG. 8F, the display panel manufacturing method may include an operation of etching the pixel-defining layer PDL and an operation of etching the preliminary sacrificial pattern SP_I (refer to FIG. 8E). The process of etching the pixel-defining layer PDL may be performed by a dry etching method, and the pixel-defining layer PDL may be etched using the second photoresist layer PR2 and the barrier wall PW (e.g., the second barrier wall layer L2) as a mask. A light-emitting opening OP-E corresponding to the barrier wall opening OP-P may be formed in the pixel-defining layer PDL.

The process of etching the preliminary sacrificial pattern SP_I may be performed by a wet etching method, and the preliminary sacrificial pattern SP_I may be etched using the second photoresist layer PR2 and the barrier wall PW (e.g., the second barrier wall layer L2) as a mask. A sacrificial opening OP-S overlapping the light-emitting opening OP-E may be formed in a sacrificial pattern SP formed by etching the preliminary sacrificial pattern SP_I. At least a portion of the anode AE may be exposed from the sacrificial pattern SP and the pixel-defining layer PDL by the sacrificial opening OP-S and the light-emitting opening OP-E.

The process of etching the sacrificial pattern SP may be performed in an environment in which the etch selectivity between the sacrificial pattern SP and the anode AE is high, and thus the likelihood of the anode AE being etched may be reduced or prevented. That is, because the sacrificial pattern SP having a higher etch rate than the anode AE is located between the pixel-defining layer PDL and the anode AE, etching of the anode AE may be reduced or prevented to avoid damage during the etching process.

Referring to FIG. 8G, the display panel manufacturing method may include an operation of forming an emission pattern EP and a cathode CE in the barrier wall opening OP-P after removing the second photoresist layer PR2. The cathode CE may contact the barrier wall PW.

The operation of forming the emission pattern EP and the cathode CE may be performed by deposition processes. The operation of forming the emission pattern EP may include a thermal evaporation process, and the operation of forming the cathode CE may include a sputtering process. However, the deposition processes for the operation of forming the emission pattern EP and the operation of forming the cathode CE are not limited thereto.

The emission pattern EP may be formed on the anode AE. In the operation of forming the emission pattern EP, the emission pattern EP may be divided by the tip portion formed in the barrier wall PW, and may be located in the light-emitting opening OP-E and the barrier wall opening OP-P. In the operation of forming the emission pattern EP, a first dummy layer D1_I spaced apart from the emission pattern EP may be formed together on the barrier wall PW.

The cathode CE may be formed on the emission pattern EP. In the operation of forming the cathode CE, the cathode CE may be divided by the tip portion formed in the barrier wall PW, and may be located in the barrier wall opening OP-P. The cathode CE may be provided at a higher incidence angle than the emission pattern EP, and may contact the side surface of the first barrier wall layer L1. In the operation of forming the cathode CE, a second dummy layer D2_I spaced apart from the cathode CE may be formed together on the barrier wall PW. The anode AE, the emission pattern EP, and the cathode CE may constitute a light-emitting element ED.

The first dummy layer D1_I and the second dummy layer D2_I may form a dummy layer DMP_I, and a dummy opening OP-D may be formed in the dummy layer DMP_I. The barrier wall opening OP-P may include a first region AA1 and a second region AA2 sequentially located in the thickness direction (that is, the third direction DR3). The first region AA1 of the dummy opening OP-D may be defined by the inner surface of the first dummy layer D1_I, and the second region AA2 of the dummy opening OP-D may be defined by the inner surface of the second dummy layer D2_I.

Referring to FIGS. 8H and 8I, the display panel manufacturing method may include an operation of forming a lower inorganic encapsulation pattern LIL making direct contact with the inorganic pattern IP on the cathode CE.

Referring to FIG. 8H, the operation of forming the lower inorganic encapsulation pattern LIL may include an operation of depositing a lower inorganic encapsulation layer LIL_I. The lower inorganic encapsulation layer LIL_I may be formed through a deposition process. In one or more embodiments, the lower inorganic encapsulation layer LIL_I may be formed through a chemical vapor deposition (CVD) process.

The lower inorganic encapsulation layer LIL_I may be deposited on the barrier wall PW and the cathode CE. In detail, one portion of the lower inorganic encapsulation layer LIL_I may be deposited in the barrier wall opening OP-P, and another portion of the lower inorganic encapsulation layer LIL_I may be deposited on the barrier wall PW. The lower inorganic encapsulation layer LIL_I may make direct contact with the inorganic pattern IP. For example, the lower inorganic encapsulation layer LIL_I may be deposited to make contact with the side surface and a portion of the upper surface of the inorganic pattern IP.

Referring to FIG. 8I, the operation of forming the lower inorganic encapsulation pattern LIL may include an operation of forming a third photoresist layer PR3, an operation of making the lower inorganic encapsulation layer LIL_I (refer to FIG. 8H) subject to patterning to form the lower inorganic encapsulation pattern LIL, and an operation making the dummy layer DMP_I (refer to FIG. 8H) subject to patterning to form dummy patterns DMP.

In the operation of forming the third photoresist layer PR3, the third photoresist layer PR3 may be formed by forming a preliminary photoresist layer, and by making the preliminary photoresist layer subject to patterning using a photo mask. Through the patterning process, the third photoresist layer PR3 may be formed in the form of a pattern corresponding to the light-emitting opening OP-E.

The operation of making the lower inorganic encapsulation layer LIL_I subject to patterning may be performed such that portions of the lower inorganic encapsulation layer LIL_I that overlap the remaining anodes (other than the corresponding anode AE) are removed by dry etching the lower inorganic encapsulation layer LIL_I. The lower inorganic encapsulation pattern LIL overlapping the corresponding light-emitting opening OP-E may be formed from the patterned lower inorganic encapsulation layer LIL_I.

The operation of making the dummy layer DMP_I subject to patterning may be performed such that portions of the first and second dummy layers D1_I and D2_I that overlap the remaining anodes other than the corresponding anode AE are removed by dry etching the first and second dummy layers D1_I and D2_I (refer to FIG. 8H).

First and second dummy patterns D1 and D2 overlapping the corresponding light-emitting opening OP-E may be formed from the patterned first and second dummy layers D1_I and D2_I, and the dummy patterns DMP including the first and second dummy patterns D1 and D2 may be formed. The first and second dummy patterns D1 and D2 may have a closed-line shape surrounding the corresponding emissive region PXA (refer to FIG. 4) when viewed from above the plane.

In one or more embodiments of the present disclosure, the display panel manufacturing method may further include an operation of additionally etching the dummy patterns DMP. For example, in the operation of additionally etching the dummy patterns DMP, the dummy patterns DMP may be removed by wet etching the dummy patterns DMP.

In one or more embodiments of the present disclosure, the display panel manufacturing method may further include an operation of additionally etching the lower inorganic encapsulation pattern LIL. In the operation of additionally etching the lower inorganic encapsulation pattern LIL, a portion of the lower inorganic encapsulation pattern LIL may be removed by dry etching the lower inorganic encapsulation pattern LIL located on the barrier wall PW. The lower inorganic encapsulation pattern LIL from which the portion of the lower inorganic encapsulation pattern LIL located on the barrier wall PW is removed may correspond to the lower inorganic encapsulation pattern LILa of FIG. 6. The lower inorganic encapsulation pattern LILa may extend along the lower surface of the second barrier wall layer L2, and may not be located on the side surface of the second barrier wall layer L2.

Referring to FIG. 8J, the display panel manufacturing method may include an operation of completing the display panel DP by forming an organic encapsulation film OL and an upper inorganic encapsulation film UIL, after removing the third photoresist layer PR3 (refer to FIG. 8I). The organic encapsulation film OL may be formed by applying an organic material using an inkjet method, but is not limited thereto. The organic encapsulation film OL provides a flat upper surface. The upper inorganic encapsulation film UIL may be formed by depositing an inorganic material. Accordingly, the display panel DP including the base layer BL, the circuit element layer DP-CL, the display element layer DP-OLED, and the thin film encapsulation layer TFE may be formed.

A operation of forming barrier wall openings and light-emitting openings corresponding to emissive regions having other colors in the barrier wall PW and the pixel-defining layer PDL, an operation of forming light-emitting elements that provide the other colors, and an operation of forming lower inorganic encapsulation patterns covering the light-emitting elements that provide the other colors, may be additionally performed between the operation of forming the lower inorganic encapsulation pattern LIL and the operation of completing the display panel DP. Accordingly, the display panel DP including first to third light-emitting elements, dummy patterns DMP, D1, and D2, and first and second lower inorganic encapsulation patterns that correspond to the plurality of emissive regions PXA-R, PXA-G, and PXA-B illustrated in FIG. 4 may be formed.

Because the inorganic pattern is coupled by making direct contact with the lower inorganic encapsulation pattern as described above, the coupling force of the lower inorganic encapsulation pattern may be improved, and the sealing ability of the lower inorganic encapsulation pattern to protect the display element layer may be improved. Accordingly, pixel defects (dark spots, pixel shrinkage, or the like) caused by foreign matter introduced from the side surface of the lower inorganic encapsulation pattern may be reduced or eliminated, and as the wet etch region is increased in the etching process operation of the lower encapsulation inorganic pattern, the mass productivity of the display panel may be improved.

In addition, because the coupling force of the lower inorganic encapsulation pattern is improved, the sealing ability of the lower inorganic encapsulation pattern may be improved even though the portion of the lower inorganic encapsulation pattern formed on the barrier wall is etched and removed, and because the first lower inorganic encapsulation pattern itself blocks foreign matter introduced from the side surface of the first lower inorganic encapsulation pattern, an additional lower inorganic encapsulation pattern (e.g., the second lower inorganic encapsulation pattern) may be omitted.

While the present disclosure has been described with reference to embodiments thereof, it will be apparent to those of ordinary skill in the art that various changes and modifications may be made thereto without departing from the spirit and scope of the present disclosure as set forth in the following claims, with functional equivalents thereof to be included therein.

What is claimed is:

1. A display panel comprising:
a base layer;
a pixel-defining layer above the base layer, and defining a light-emitting opening;
a barrier wall defining a barrier wall opening overlapping the light-emitting opening, the barrier wall comprising a first barrier wall layer above the pixel-defining layer, and a second barrier wall layer above the first barrier wall layer;
an inorganic pattern above the first barrier wall layer; and
a light-emitting element in the barrier wall opening, and comprising an anode, an intermediate layer, and a cathode contacting the barrier wall.

2. The display panel of claim 1, wherein the inorganic pattern protrudes further toward a center of the barrier wall opening in plan view than the first barrier wall layer.

3. The display panel of claim 1, wherein the first barrier wall layer comprises a first sub-barrier wall layer above the pixel-defining layer, and a second sub-barrier wall layer above the first sub-barrier wall layer, and
wherein the inorganic pattern is between the first sub-barrier wall layer and the second sub-barrier wall layer.

4. The display panel of claim 3, wherein the cathode contacts the first sub-barrier wall layer.

5. The display panel of claim 3, wherein the barrier wall opening comprises:
a first region defined by a side surface of the first sub-barrier wall layer;
a second region defined by a side surface of the inorganic pattern;
a third region defined by a side surface of the second sub-barrier wall layer; and
a fourth region defined by a side surface of the second barrier wall layer, and
wherein the first to fourth regions are integrally formed in a thickness direction of the base layer.

6. The display panel of claim 3, wherein the inorganic pattern comprises a first inorganic pattern above the first sub-barrier wall layer and, a second inorganic pattern above the first inorganic pattern and covered by the second sub-barrier wall layer.

7. The display panel of claim 6, wherein a thickness of the first inorganic pattern is less than a thickness of the second inorganic pattern.

8. The display panel of claim 6, wherein the first inorganic pattern comprises transparent conductive oxide (TCO), and
wherein the second inorganic pattern comprises an insulating material.

9. The display panel of claim 1, wherein a width of the inorganic pattern is less than a width of the barrier wall.

10. The display panel of claim 1, wherein a region where an upper surface of the anode is exposed by the light-emitting opening and the barrier wall opening is defined as an emissive region, and
wherein the inorganic pattern surrounds the emissive region in plan view.

11. The display panel of claim 1, further comprising a lower inorganic encapsulation pattern above the cathode, and directly contacting the inorganic pattern.

12. The display panel of claim 11, wherein one portion of the lower inorganic encapsulation pattern is in the barrier wall opening, and another portion of the lower inorganic encapsulation pattern is above the barrier wall.

13. The display panel of claim 11, wherein the lower inorganic encapsulation pattern is in the barrier wall opening.

14. A display panel comprising:
a base layer;
a pixel-defining layer above the base layer, and defining a light-emitting opening;
a barrier wall above the pixel-defining layer, and defining a barrier wall opening overlapping the light-emitting opening;
a light-emitting element in the barrier wall opening, and comprising an anode, an intermediate layer, and a cathode contacting the barrier wall; and
an inorganic pattern surrounding, in plan view, an emissive region where an upper surface of the anode is exposed by the light-emitting opening and the barrier wall opening.

15. The display panel of claim 14, wherein the barrier wall comprises:
a first barrier wall layer comprising a first sub-barrier wall layer above the pixel-defining layer, and a second sub-barrier wall layer above the first sub-barrier wall layer; and
a second barrier wall layer above the first barrier wall layer, and
wherein the inorganic pattern is between the first sub-barrier wall layer and the second sub-barrier wall layer.

16. The display panel of claim 15, wherein the barrier wall opening comprises:
a first region defined by a side surface of the first sub-barrier wall layer;
a second region defined by a side surface of the inorganic pattern;
a third region defined by a side surface of the second sub-barrier wall layer; and
a fourth region defined by a side surface of the second barrier wall layer, and
wherein the first to fourth regions are integrally formed in a thickness direction of the base layer.

17. The display panel of claim 15, wherein the inorganic pattern comprises a first inorganic pattern above the first sub-barrier wall layer, and a second inorganic pattern above the first inorganic pattern and covered by the second sub-barrier wall layer,
wherein the first inorganic pattern comprises transparent conductive oxide (TCO), and
wherein the second inorganic pattern comprises an insulating material.

18. The display panel of claim 14, further comprising a lower inorganic encapsulation pattern above the cathode, and directly contacting the inorganic pattern.

19. The display panel of claim 18, wherein one portion of the lower inorganic encapsulation pattern is in the barrier wall opening, and another portion of the lower inorganic encapsulation pattern is above the barrier wall.

20. The display panel of claim 18, wherein the lower inorganic encapsulation pattern is in the barrier wall opening.

21. A method for manufacturing a display panel, the method comprising:
providing a preliminary display panel comprising a base layer, and a pixel-defining layer above the base layer;
depositing a first preliminary sub-barrier wall layer above the preliminary display panel;
depositing an inorganic layer above the first preliminary sub-barrier wall layer;
forming an inorganic pattern by etching the inorganic layer;
depositing a second preliminary sub-barrier wall layer and a preliminary metal barrier wall layer above the first preliminary sub-barrier wall layer and the inorganic pattern; and
forming a barrier wall defining a barrier wall opening by etching the first preliminary sub-barrier wall layer, the second preliminary sub-barrier wall layer, and the preliminary metal barrier wall layer.

22. The method of claim 21, wherein the depositing of the inorganic layer comprises:
depositing a first inorganic layer comprising transparent conductive oxide (TCO) above the first preliminary sub-barrier wall layer; and
depositing a second inorganic layer comprising an insulating material above the first inorganic layer.

23. The method of claim 22, wherein the forming of the inorganic pattern comprises:
forming a first inorganic pattern by etching the first inorganic layer; and
forming a second inorganic pattern by etching the second inorganic layer.

24. The method of claim 21, wherein the forming of the barrier wall comprises:
etching the first preliminary sub-barrier wall layer, the second preliminary sub-barrier wall layer, and the preliminary metal barrier wall layer; and
forming a first sub-barrier wall layer, a second sub-barrier wall layer, and a metal barrier wall layer by etching the first preliminary sub-barrier wall layer and the second preliminary sub-barrier wall layer.

25. The method of claim 24, wherein the forming of the first sub-barrier wall layer, the second sub-barrier wall layer, and the metal barrier wall layer comprises:
etching the first preliminary sub-barrier wall layer and the second preliminary sub-barrier wall layer such that the inorganic pattern protrudes further toward a center of the barrier wall opening, in plan view, than the first sub-barrier wall layer and the second sub-barrier wall layer.

26. The method of claim 21, further comprising:
forming, in the barrier wall opening, an emission pattern and a cathode contacting the barrier wall; and
forming, above the cathode, a lower inorganic encapsulation pattern configured to make direct contact with the inorganic pattern.
